(19) United States
(12) Patent Application Publication
(10) Pub. No.: US 2026/0265953 A1
(43) Pub. Date: Sep. 10, 2026

(54) EPITAXIAL GROWTH SUBSTRATE, METHOD OF PRODUCING EPITAXIAL GROWTH SUBSTRATE, AND SEMICONDUCTOR ELEMENT

(71) Applicant: DOWA Electronics Materials Co., Ltd., Tokyo (JP)

(72) Inventors: Kiyoka IMAI, Akita-shi (JP); Yoshitaka KADOWAKI, Akita-shi (JP)

(73) Assignee: DOWA Electronics Materials Co., Ltd., Tokyo (JP)

(21) Appl. No.: 19/466,809

(22) Filed: Feb. 2, 2026

(30) Foreign Application Priority Data
Mar. 7, 2025 (JP) 2025-036706

(51) Int. Cl. C30B 29/40; C30B 23/02; C30B 25/18; H10F 71/00; H10H 20/01

(52) U.S. Cl. CPC C30B 29/40; C30B 23/025; C30B 25/18; H10F 71/1272; H10H 20/012

(57) ABSTRACT

Provided is an epitaxial growth substrate that can impart excellent performance to an optical semiconductor element. The epitaxial growth substrate includes an off substrate having a lattice constant a_{g} and an off angle θ and a plurality of composition inclined layers stacked such that a lattice constant difference with the off substrate increases gradually from an off substrate-side. A composition inclined layer furthest from the off substrate is taken to be a pseudo substrate layer. A degree of mismatch Xα_{p·g} that, using a surface lattice constant a_{g}′ calculated from the lattice constant a_{g} and the off angle θ by formula (1): a_{g}′=a_{g}/cosθ and a strain-affected lattice constant bₚ of the pseudo substrate layer calculated from X-ray diffraction measurement results, is calculated by formula (2): Xα_{p·g}=(bₚ−a_{g}′)/a_{g}′, is 0.5% or less.

### TECHNICAL FIELD

The present disclosure relates to an epitaxial growth substrate, a method of producing an epitaxial growth substrate, and a semiconductor element.

### BACKGROUND

Optical semiconductor elements that include a substrate and a semiconductor layer that is formed on the substrate by epitaxial growth and that has a different lattice constant to the substrate are conventionally known in the art.

In recent years, attempts have been made to improve the crystallinity of semiconductor layers such as active layers included in optical semiconductor elements and to enhance the characteristics of optical semiconductor elements. As one example, Patent Literature (PTL) 1 discloses an epitaxial wafer and an element produced using the epitaxial wafer that provide improved crystallinity of an active layer in the epitaxial wafer and enhanced characteristics. The disclosed epitaxial wafer and element produced using the epitaxial wafer include a substrate, a buffer layer formed on the substrate, an active layer formed on the buffer layer and composed of an epitaxial film having a larger lattice constant than a lattice constant of a material forming the substrate, and a covering layer composed of one layer or a plurality of layers that is formed on the active layer and disposed in contact with the active layer, wherein a lattice constant of a layer in contact with the active layer, among constituent layers of the coating layer, is smaller than whichever is larger among the lattice constant of the active layer and a lattice constant of the buffer layer, and the thickness of the coating layer is not less than 0.2 μm and not more than 2.0 μm. PTL 1 also discloses the provision of a step layer between the substrate and the buffer layer, wherein this step layer is composed of a plurality of layers configured such that a lattice constant increases gradually from the substrate-side.

### CITATION LIST

### Patent Literature

PTL 1: JP 2006-80448 A

### SUMMARY

However, an optical semiconductor element such as the epitaxial wafer and element produced using the same in PTL 1 is inadequate in terms of improving crystallinity of a semiconductor layer such as an active layer and further enhancing performance of the optical semiconductor element, and there is room for further improvement.

Accordingly, one object of the present disclosure, which was made in view of the problem set forth above, is to provide an epitaxial growth substrate that can impart excellent performance to an optical semiconductor element.

Another object of the present disclosure is to provide a method of producing an epitaxial growth substrate that can impart excellent performance to an optical semiconductor element.

Yet another object of the present disclosure is to provide an optical semiconductor element having excellent performance.

The inventor conducted diligent research to solve the problem set forth above. Conventionally, even in a case in which a substrate 11 having an off angle θ has been used, lattice constant differences with layers on the substrate 11 have normally been considered with a lattice constant a_{g} of the substrate 11 as a reference (i.e., without taking into account the off angle θ) because, as illustrated in FIG. 1, growth occurs in a lateral direction (direction of arrow A) such as to fill in a step S during epitaxial growth. However, a step layer (corresponding to a subsequently described “composition inclined layer” in the present disclosure) and a buffer layer (corresponding to a subsequently described “pseudo substrate layer” in the present disclosure) where there is a stepwise increase of lattice constant experience compressive strain due to compression and have an actual lattice constant that is smaller than a theoretical lattice constant calculated from the composition. The inventor found that when interposing a composition inclined layer on an off substrate 11 to reduce the degree of mismatch with a lattice constant of a pseudo substrate layer thereon having compressive strain and improve crystallinity of the pseudo substrate layer, there is a difference between a case in which the off angle of the off substrate is small and a case in which the off angle of the off substrate is large, and discovered that it is inadequate to just take into consideration the lattice constant a_{g} as a reference as has conventionally been done.

The inventor discovered that when an epitaxial growth substrate is formed using an off substrate having a lattice constant a_{g} and an off angle θ, designing the epitaxial growth substrate such that a degree of mismatch between a lattice constant a_{g}′ of a pseudo surface taking into account the off angle θ of the off substrate and a lattice constant bₚ of a pseudo substrate layer after being subjected to compression (i.e., having compressive strain) is within a specific range, crystallinity of the pseudo substrate layer improves, the negative influence of excess strain on a semiconductor layer formed on the pseudo substrate layer decreases, and improvement of performance can be imparted to an optical semiconductor element (for example, improvement of light emission efficiency in the case of a light-emitting element, reduction of dark current in the case of a light-receiving element, improvement of mobility in the case of an electronic device, etc.). In this manner, the inventor completed the present disclosure set forth below.

Specifically, primary configurations of the present disclosure are as set forth below.
[1] An epitaxial growth substrate comprising:
an off substrate having a lattice constant a_{g} and an off angle θ; and
a plurality of composition inclined layers stacked such that a lattice constant difference with the off substrate increases gradually from an off substrate-side, wherein
a composition inclined layer furthest from the off substrate is taken to be a pseudo substrate layer, and
a degree of mismatch Xα_{p·g} that, using a surface lattice constant a_{g}′ calculated from the lattice constant a_{g} and the off angle θ by formula (1), shown below:

$${a}_{g} ’ = {a}_{g} / cos θ \qquad ( 1 )$$

and a strain-affected lattice constant bₚ of the pseudo substrate layer calculated from X-ray diffraction measurement results, is calculated by formula (2), shown below:

$$X {α}_{p \cdot g} = ( {b}_{p} - {a}_{g} ’ ) / {a}_{g} ’ \qquad ( 2 )$$

is 0.5% or less.
[2] The epitaxial growth substrate according to [1], wherein a degree of mismatch Xβ_{p·g} calculated by formula (3), shown below:

$$X {β}_{p \cdot g} = ( {b}_{p} - {a}_{g} ) / {a}_{g} \qquad ( 3 )$$

is more than 0.5%, and
the degree of mismatch Xα_{p·g} is not less than −3.0% and not more than 0.5%.
[3] The epitaxial growth substrate according to [1] or [2], wherein the off angle θ is not less than 4° and not more than 44°.
[4] The epitaxial growth substrate according to any one of [1] to [3], wherein the plurality of composition inclined layers are stacked such that a degree of mismatch Y of a lattice constant of a composition inclined layer relative to a lattice constant of a layer adjacent thereto at an off substrate-side is not less than 0.05% and not more than 0.3%.
[5] The epitaxial growth substrate according to any one of [1] to [4], wherein the off substrate is an InP substrate, and the composition inclined layers are InAsP layers or InAlAs layers.
[6] The epitaxial growth substrate according to any one of [1] to [5], wherein the pseudo substrate layer is a thickest layer among the composition inclined layers, and the pseudo substrate layer has a thickness of 300 nm or more.
[7]A method of producing an epitaxial growth substrate comprising a step of stacking, on an off substrate having a lattice constant a_{g} and an off angle θ, a plurality of composition inclined layers such that a lattice constant difference with the off substrate increases gradually from an off substrate-side, wherein
a composition inclined layer furthest from the off substrate is taken to be a pseudo substrate layer, and
the pseudo substrate layer is formed such that a degree of mismatch Xα_{p·g} that, using a surface lattice constant a_{g}′ calculated from the lattice constant a_{g} and the off angle θ by formula (1), shown below:

$${a}_{g} ’ = {a}_{g} / cos θ \qquad ( 1 )$$

and a strain-affected lattice constant bₚ of the pseudo substrate layer calculated from X-ray diffraction measurement results, is calculated by formula (2), shown below:

$$X {α}_{p \cdot g} = ( {b}_{p} - {a}_{g} ’ ) / {a}_{g} ’ \qquad ( 2 )$$

is 0.5% or less.
[8] An optical semiconductor element obtained using the epitaxial growth substrate according to any one of [1] to [6], comprising a semiconductor layer that is provided at a surface of the pseudo substrate layer of the epitaxial growth substrate and that is lattice matched with the pseudo substrate layer.

According to the present disclosure, it is possible to provide an epitaxial growth substrate that can impart excellent performance to an optical semiconductor element.

Moreover, according to the present disclosure, it is possible to provide a method of producing an epitaxial growth substrate that can impart excellent performance to an optical semiconductor element.

Furthermore, according to the present disclosure, it is possible to provide an optical semiconductor element having excellent performance.

### BRIEF DESCRIPTION OF THE DRAWINGS

In the accompanying drawings:

FIG. 1 is a schematic view for describing epitaxial growth and an off angle;

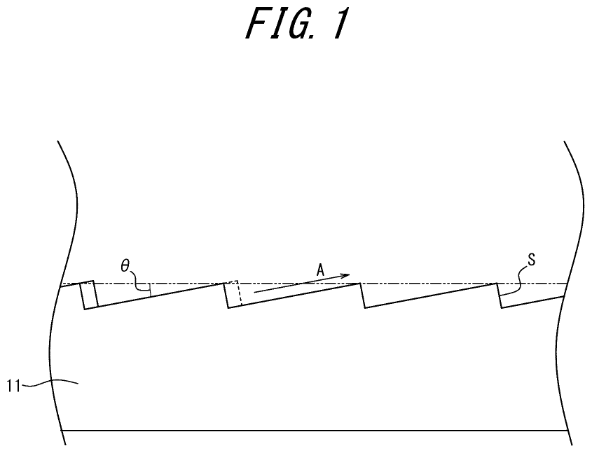

FIG. 2 is a schematic view illustrating an example of an epitaxial growth substrate according to the present disclosure; and

FIG. 3 is a schematic view illustrating an example of a semiconductor light-receiving element that is one embodiment of an optical semiconductor element according to the present disclosure.

### DETAILED DESCRIPTION

(Terminology and measurement methods) First, the following points are described in advance of describing embodiments.

An off angle θ of an off substrate in the present specification can be confirmed using an X-ray diffractometer (XRD). For example, in the case of an off substrate that is an InP substrate, the off angle is investigated by using an XRD to perform rocking curve measurement with respect to (400) planes of the InP substrate. Specifically, rotation is performed around the P axis while implementing ω scan orientation measurement (half+ω scan at four orientations of φ=0°, 90°, 180°, 270°) in XRD measurement of the substrate, the offset angle of (400) planes relative to the substrate surface is determined from the angle of ω, and this offset angle is taken to be the off angle θ.

Note that the upper limit for the off angle θ of an off substrate is normally 45°.

In the present specification, a lattice constant that has been calculated according to Vegard's law based on composition is allotted the symbol “a”, and the layer to which the lattice constant corresponds is indicated by subscript accompanying the symbol “a”. For example, a lattice constant of an off substrate (initial growth substrate) is denoted as a_{g}, a lattice constant of a pseudo substrate layer is denoted as ap, and a lattice constant of a composition inclined layer is denoted as a_{c}.

A degree of mismatch Xα, a degree of mismatch Xβ, and a degree of mismatch Y referred to in the present specification are each a value calculated by Δa/a, where Δa is the difference between the lattice constants a of two layers, expressed as a percentage (%). For example, a degree of mismatch Y of a layer L2 relative to a layer L1 may be denoted as Y_{L2·L1} and can be calculated by (a_{L2}−a_{L1})/a_{L1}.

Note that the term “lattice matched” as used in the present specification means that the degree of mismatch is within ±0.1%.

A surface lattice constant a_{g}′ of an off substrate taking into account the off angle θ in the present specification is a value calculated by dividing a lattice constant a_{g} of the off substrate by cosθ (θ is the off angle) and, more specifically, is calculated by the following formula (1).

$${a}_{g} ’ = {a}_{g} / cos θ \qquad ( 1 )$$

Composition ratios of each layer in the present specification can be taken to be values obtained through SIMS analysis. For example, composition ratios of each layer among a plurality of composition inclined layers in the present specification can be taken to be values obtained by implementing SIMS analysis (quadrupole type) in a thickness direction from a pseudo substrate layer in the case of an epitaxial growth substrate. On the other hand, in the case of an optical semiconductor element, values obtained by implementing SIMS analysis (quadrupole type) in a thickness direction from a window layer can be adopted. Note that for SIMS analysis results, a value of the average element concentration in a half-thickness range at a central part of each layer in a thickness direction of the layer can be adopted.

In production, a layer having target composition ratios can be stacked by using growth conditions that are determined such as to give the target composition ratios by calculating composition ratios using a lattice constant according to XRD measurement and a value determined through conversion of a central emission wavelength according to photoluminescence (PL) measurement to Eg (i.e., a band gap) for a layer grown as a single film (for example, refer to procedure (A) in calculation of degree of relaxation R described further below).

In the present specification, a lattice constant a is taken to be a value calculated according to Vegard's law based on composition ratios unless otherwise specified.

First, a simple lattice constant for a mixed crystal is calculated in accordance with Vegard's law.

Using an InGaAsP system (i.e., a general formula: (InₐGa_{b})(PₓAs_{y})) as an example, a physical property constant A_{abxy} (lattice constant according to Vegard's law) is calculated by the following formula (4) based on physical property constants Bₐₓ, B_{bx}, B_{ay}, and B_{by} (literature value lattice constants shown below in Table 1) for the four binary mixed crystals that are the basis for the quasi-quaternary mixed crystal in a case in which each composition ratio is known.

$${A}_{abxy} = a \times x \times {B}_{ax} + b \times x \times {B}_{bx} + a \times y \times {B}_{ay} + b \times y \times {B}_{by} \qquad ( 4 )$$

TABLE 1

| | Lattice constant a [nm] | Eg [eV] |
|---|---|---|
| InP | 0.5869 | 1.35 |
| GaP | 0.5451 | 2.26 |
| InAs | 0.6058 | 0.354 |
| GaAs | 0.5653 | 1.42 |

In the case of a quasi-ternary mixed crystal, when a general formula: (InₐGa_{b}Al_{c})(As) is taken as an example, the band gap Eg and lattice constant a according to Vegard's law can be calculated from the following formulae (5) and (6).

$$E {g}_{abcy} = ( a \times b \times {E}_{aby} + b \times c \times {E}_{bcy} + c \times a \times {E}_{acy} ) / ( a \times b + b \times c + c \times a ) \qquad ( 5 )$$

$${A}_{abcy} = a \times {B}_{ay} + b \times {B}_{by} + c \times {B}_{cy} \qquad ( 6 )$$

Note that even in the case of a ternary, pentanary, or hexanary III-V compound semiconductor, the composition wavelength and lattice constant can be determined by modifying the formulae according to the same reasoning as described above. Moreover, in the case of a binary III-V compound semiconductor, the aforementioned literature values can be used.

In the present specification, when referring simply to “InGaAsP” without clearly stating composition ratios, this means any compound in which a chemical composition ratio of group III elements (total of In and Ga) and group V elements (As and P) is 1:1 and in which a ratio of the group III elements In and Ga and a ratio of the group V elements As and P are undefined.

This case also encompasses a case in which either In or Ga is not included among group III element and a case in which either As or P is not included among group V element. In other words, “InGaAsP” can be denoted as “In_{y}Ga_{1-y}AsₓP₁₋ₓ”, where x and y each independently represent a value of not less than 0 and not more than 1.

Moreover, when referring to “InGaP”, this means that As is not included in “InGaAsP” described above with the exception of unavoidable contamination during production, and when referring to “InGaAs”, this means that P is not included in “InGaAsP” described above with the exception of unavoidable contamination during production. In other words, “InGaP” can be denoted as “In_{y}Ga_{1-y}P” and “InGaAs” can be denoted as “In_{y}Ga_{1-y}As”, where y represents a value of not less than 0 and not more than 1.

Likewise, when referring to “InAsP”, this means that Ga is not included in “InGaAsP” described above with the exception of unavoidable contamination during production, and when referring to “GaAsP”, this means that In is not included in “InGaAsP” described above with the exception of unavoidable contamination during production. In other words, “InAsP” can be denoted as “InAsₓP₁₋ₓ” and “GaAsP” can be denoted as “GaAsₓP₁₋ₓ”, where x represents a value of not less than 0 and not more than 1.

Furthermore, when referring to “InP”, this means that Ga and As are not included in “InGaAsP” described above with the exception of unavoidable contamination during production.

Note that the composition ratio of each component in InGaAsP, InGaAs, or the like can be measured by photoluminescence measurement, XRD measurement, or the like.

Also note that the phrase “unavoidable contamination during production” refers not only to unavoidable contamination due to a production apparatus where a feedstock gas is used, but also due to diffusion of atoms at interfaces between layers during crystal growth or in accompaniment to subsequent heat treatment, for example.

In the present specification, a layer that functions electrically as a p-type is referred to as a p-type layer, and a layer that functions electrically as an n-type is referred to as an n-type layer. On the other hand, the term “undoped” means that a specific impurity such as Si, Zn, S, Sn, or Mg is not intentionally added. An undoped InGaAsP layer may contain impurities that are unavoidably mixed in during a production process. Specifically, when a layer has a low carrier density (for example, less than 4×10¹⁶/cm³), the layer is treated as “undoped” in the present specification. Values for concentrations of impurities such as Si, Zn, S, Sn, and Mg are taken to be values according to SIMS analysis.

In the present specification, a strain-affected lattice constant (lattice constant inclusive of strain) of each layer calculated from XRD measurement results is denoted as b. For example, a strain-affected lattice constant of a pseudo substrate layer is denoted as bₚ.

Moreover, the strain-affected lattice constant bₚ of a pseudo substrate layer is determined by, with respect to an epitaxial growth substrate that has been grown up to the pseudo substrate layer, performing XRD measurement using an X-ray diffractometer D8 produced by Bruker, measuring Δθ of the pseudo substrate layer through reciprocal space mapping (RSM) of (004) planes, for example, further measuring a PL wavelength of the pseudo substrate layer using a photoluminescence (PL) measurement apparatus RPMBlue produced by Onto Innovation, using the determined Δθ and PL wavelength to calculate a degree of relaxation R, and then using the determined degree of relaxation R to calculate the strain-affected lattice constant bₚ of the pseudo substrate layer in analysis software (Jordan Valley RADS).

For example, in a case in which the pseudo substrate layer is an InAsP layer, the determined Δθ and PL wavelength can be used to calculate the degree of relaxation R according to the following procedures (A) to (E), and then the determined degree of relaxation R can be used to calculate the strain-affected lattice constant bₚ of the pseudo substrate layer in analysis software (Jordan Valley RADS).

(A) Since a relationship between energy E and wavelength k is as indicated in the following formula (7):

$$E = hc / λ \qquad ( 7 )$$

(in formula (7), h represents Planck's constant and c represents the speed of light), and since energy E in the case of InAsₓP₁₋ₓ is indicated by the following formula (8):

$$E = 1.351 - 1.315 x + 0.32 {x}^{2} \qquad ( 8 )$$

(refer to “Semiconductor Lasers” (First Edition, 1994), authored and edited by IGA Kenichi, edited by The Japan Society of Applied Physics, published by Ohmsha, Ltd.), the composition of InAsₓP₁₋ₓ can be calculated so long as the PL wavelength can be determined.

(B) A lattice constant a of a ternary mixed crystal can be approximately expressed using Vegard's law. In the case of InAsₓP₁₋ₓ, the lattice constant is as indicated in the following formula (9) using the lattice constant a_{InAs} of InAs and the lattice constant a_{InP} of InP.

$${a}_{InAsP} = {a}_{InAs} x + {a}_{InP} ( 1 - x ) \qquad ( 9 )$$

(C) Since a c-axis lattice constant a_{strain:c} when an epitaxial film is under complete compressive strain (i.e., when the lattice constant of the epitaxial film is matched with an off substrate) is as indicated in the following formula (10):

$${a}_{strain : c}^{epi} = {a}_{relax}^{epi} - 2 {C}_{12} / {C}_{11} ( {a}^{sub} - {a}_{relax}^{epi} ) \qquad ( 10 )$$

since a^{epi}ᵣₑₗₐₓ in formula (10), in the case of InAsₓP₁₋ₓ, is as indicated in the following formula (11):

$${a}_{relax}^{epi} = {a}_{InAsP} \qquad ( 11 )$$

and since an elastic constant C₁₁ in formula (10) represents resistance to distortion in an x-axis direction when the c-axis is taken to be the z-axis and stress is applied in the x-axis direction to a plane orthogonal to the x-axis, an elastic constant C₁₂ in formula (10) represents resistance to distortion in a y-axis direction when the c-axis is taken to be the z-axis and stress is applied in the x-axis direction to a plane orthogonal to the x-axis, and the elastic constant C₁₁ and the elastic constant C₁₂ are as indicated in the following formulae (12) and (13) using values resulting from linear combination of elastic constant values of InAs and InP:

$${C}_{11} = {C}_{11}^{InAs} x + {C}_{11}^{InP} ( 1 - x ) \qquad ( 12 )$$

$${C}_{12} = {C}_{12}^{InAs} x + {C}_{12}^{InP} ( 1 - x ) \qquad ( 13 )$$

a^{epi}_{strain:c} can be determined by formulae (10) to (13).

(D) Since the angle of X-ray diffraction when the lattice constant of an epitaxial film is a^{epi} is, according to Bragg's equation, indicated by the following formula (14):

$${a}^{e p i} sin {θ}^{e p i} = 2 λ \qquad ( 14 )$$

and conversion thereof gives the following formula (15):

$${θ}^{e p i} = arcsin ( 2 λ / {a}^{e p i} ) \qquad ( 15 )$$

the theoretical value of Δθ when the diffraction angle of the off substrate is θ^{sub} is as indicated in the following formula (16).

$$Δ θ = {θ}^{e p i} - {θ}^{sub} \qquad ( 16 )$$

(E) The degree of relaxation R is defined by the following formula (17):

$$R = ( Δ {θ}_{strain} - Δ θ ) / ( Δ {θ}_{strain} - Δ {θ}_{r e l a x} ) \qquad ( 17 )$$

according to how close the measurement value Δθ is to a value for complete relaxation relative to theoretical values (Bᵣₑₗₐₓ, θₛₜᵣₐᵢₙ) for complete relaxation and complete compressive strain. The degree of relaxation R that has been obtained in this manner can be used to calculate the strain-affected lattice constant bₚ of the pseudo substrate layer in analysis software (Jordan Valley RADS). Moreover, in a case in which a semiconductor layer such as a light-absorbing layer has been formed on the pseudo substrate layer, a strain-affected lattice constant b of that semiconductor layer can be determined through XRD measurement and calculation carried out with respect to the semiconductor layer in the same manner as described above.

In the present specification, a degree of mismatch Xα_{p·g} of a pseudo substrate layer relative to an off substrate is calculated by the following formula (2):

$$X {α}_{p \cdot g} = ( {b}_{p} - {a}_{g}^{′} ) / {a}_{g}^{′} \qquad ( 2 )$$

using a lattice constant bₚ of the pseudo substrate layer and a surface lattice constant a_{g}′ that takes into account an off angle of the off substrate, and the resultant value is expressed as a percentage (%).

In the present specification, a degree of mismatch Xβ_{p·g} of a pseudo substrate layer relative to an off substrate is calculated by the following formula (3):

$$X {β}_{p \cdot g} = ( {b}_{p} - {a}_{g} ) / {a}_{g} \qquad ( 3 )$$

using a lattice constant bₚ of the pseudo substrate layer and a lattice constant a_{g} that does not take into account an off angle of the off substrate, and the resultant value is expressed as a percentage (%).

In the present specification, the overall thickness of each formed layer can be measured using an optical interference film thickness meter. Moreover, the thickness of each layer can be calculated using an optical interference film thickness meter and cross-section observation of a layer through a transmission electron microscope. Furthermore, in a case in which each layer has a small thickness such as in a superlattice structure, the thickness can be measured using TEM-EDS. Note that when a certain layer has a tilted surface in a cross-sectional view, the thickness of that layer is taken to be the maximum height from a flat surface of a layer directly below that layer.

### (Epitaxial Growth Substrate)

An epitaxial growth substrate according to the present disclosure includes an off substrate having a lattice constant a_{g} and an off angle θ and a plurality of composition inclined layers stacked such that a lattice constant difference with the off substrate increases gradually from an off substrate-side. Moreover, in the epitaxial growth substrate according to the present disclosure, a composition inclined layer furthest from the off substrate is taken to be a pseudo substrate layer, and a degree of mismatch Xα_{p·g} that, using a surface lattice constant a_{g}′ calculated from the lattice constant a_{g} and the off angle θ of the off substrate by formula (1), shown below:

$${a}_{g}^{′} = {a}_{g} / cos θ \qquad ( 1 )$$

and a strain-affected lattice constant bₚ of the pseudo substrate layer calculated from X-ray diffraction measurement results, is calculated by formula (2), shown below:

$$X {α}_{p \cdot g} = ( {b}_{p} - {a}_{g}^{′} ) / {a}_{g}^{′} \qquad ( 2 )$$

is 0.5% or less.

Improved crystallinity of a pseudo substrate layer in an epitaxial growth substrate such as set forth above is presumed to reduce the negative influence of excess strain on a semiconductor layer formed thereon, thereby enabling the epitaxial growth substrate to impart excellent performance to an optical semiconductor element.

Note that the epitaxial growth substrate according to the present disclosure can be obtained by a subsequently described method of producing an epitaxial growth substrate according to the present disclosure.

The epitaxial growth substrate according to the present disclosure may optionally include another layer between the off substrate and a composition inclined layer that is closest to the off substrate (hereinafter, also referred to as a “proximal layer”).

The other layer may be a buffer layer or the like, for example.

### <Properties of Epitaxial Growth Substrate>

In the epitaxial growth substrate according to the present disclosure, the degree of mismatch Xα_{p·g} is 0.5% or less, and is preferably 0.15% or less, and more preferably −1.5% or less.

When the degree of mismatch Xα_{p·g} is not more than any of the upper limits set forth above, crystallinity of the pseudo substrate layer can be effectively improved.

Moreover, the degree of mismatch Xα_{p·g} is preferably −3.0% or more.

In the epitaxial growth substrate according to the present disclosure, the degree of mismatch Xβ_{p·g} is preferably more than 0.5%, and more preferably 0.6% or more. When a pseudo substrate layer is formed that has a large degree of mismatch Xβ_{p·g} with the lattice constant a_{g} of the substrate that does not take into account the off angle in this manner, the effect of setting the above-described degree of mismatch Xα_{p·g} that does take into account the off angle as not more than any of the upper limits set forth above is large.

Note that the degree of mismatch Xβ_{p·g} is 3.0% or less, for example, and may be 2.0% or less.

### <Structure of Epitaxial Growth Substrate>

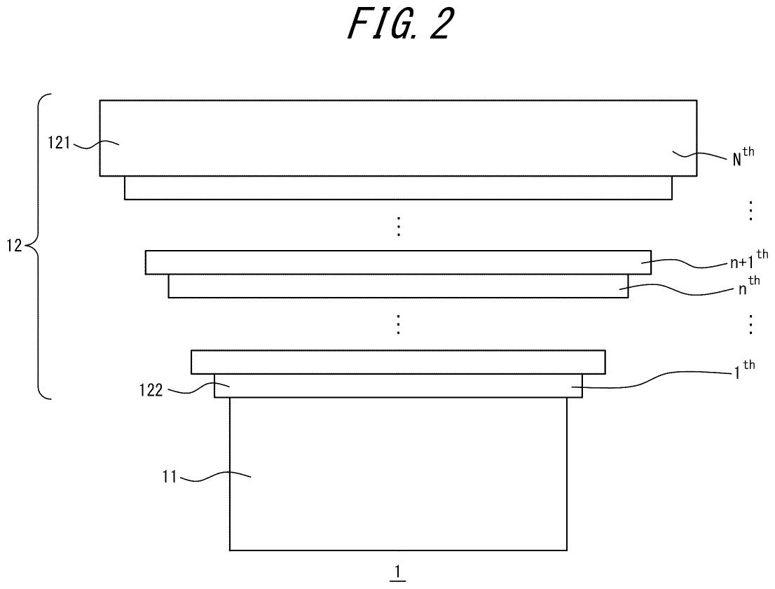

The following describes the structure of the epitaxial growth substrate with reference to FIG. 2, but the epitaxial growth substrate according to the present disclosure is not limited to the following. Note that in FIG. 2, aspect ratios of a substrate and each layer are illustrated in an exaggerated manner without consideration of their actual thickness in order to facilitate description, but that the size of the horizontal direction width of each layer relatively expresses the size of the lattice constant.

FIG. 2 is a schematic view illustrating one example of the epitaxial growth substrate according to the present disclosure. In the schematic view, changes of lattice constant are graphically represented, and the size of the horizontal direction width of each layer relatively expresses the size of the lattice constant as mentioned above.

An epitaxial growth substrate 1 illustrated in FIG. 2 includes an off substrate 11 and a plurality of composition inclined layers 12 (n is a natural number of 2 or more). A composition inclined layer 12 that is furthest from the off substrate 11 (N^{th} composition inclined layer 12) is a pseudo substrate layer 121, and a composition inclined layer 12 that is closest to the off substrate 11 (1^{st} composition inclined layer 12) is a proximal layer 122.

The number of composition inclined layers 12 corresponds to the value of N.

Although not illustrated, another layer may be provided between the off substrate 11 and the proximal layer 122.

### <Off Substrate>

No specific limitations are placed on the off substrate so long as the degree of mismatch Xα_{p·g}, etc. satisfy specific requirements. The off substrate can be a compound semiconductor substrate such as an InP substrate, a GaAs substrate, a GaSb substrate, an InAs substrate, or an InSb substrate that is selected as appropriate according to the composition of a semiconductor layer of an optical semiconductor element that is to be produced using the epitaxial growth substrate, and is preferably an InP substrate.

Note that the off substrate may be an n-type substrate or may be a p-type substrate.

The off substrate may be a substrate that is doped with S (sulfur) or the like, or may be undoped and may be semi-insulating, but the off substrate is preferably doped with S or the like in a situation in which electrical conductivity is required.

In a situation in which the off substrate is required to have electrical conductivity and is a doped substrate, the carrier density is 1.0×10¹⁶/cm³ or more, for example, and may be 1.0×10¹⁷/cm³ or more. Moreover, the carrier density is 1.0×10²⁰/cm³ or less, for example, and may be 1.0×10¹⁹/cm³ or less.

The substrate diameter can normally be selected from a range of 2 inches to 6 inches. The thickness of the off substrate is dependent on the substrate diameter but can be set as 100 μm or more, and preferably set as 300 μm or more. The use of an off substrate that is based on SEMI standards is preferable.

The off angle θ of the off substrate is not specifically limited so long as the degree of mismatch Xα_{p·g}, etc. satisfy specific requirements, but is preferably 4° or more, and more preferably 5° or more. Moreover, the off angle θ is preferably 440 or less, and more preferably 250 or less.

### <Plurality of Composition Inclined Layers>

The plurality of composition inclined layers are stacked on the off substrate such that a lattice constant difference with the off substrate increases gradually from an off substrate-side. The number of composition inclined layers is taken to be N, and this number is set as appropriate depending on the lattice constant difference with the off substrate and the pseudo substrate layer.

The “lattice constant difference with the off substrate” described above means the difference (Δa=a_{c}−a_{g}) between a lattice constant a_{c} of each composition inclined layer and a lattice constant a_{g} of the off substrate. Among the plurality of composition inclined layers, a composition inclined layer furthest from the off substrate (N^{th} composition inclined layer) is taken to be a pseudo substrate layer, and a composition inclined layer closest to the off substrate (1^{st} composition inclined layer) is taken to be a proximal layer. Note that in the plurality of composition inclined layers, the composition may, on the whole, be inclined continuously or inclined in a stepwise manner, or may be a combination thereof. However, inclination of the composition in a stepwise manner is preferable. In the case of stepwise inclination, although the composition in each individual composition inclined layer may be constant, it is also permissible to adopt a configuration in which a thin layer with an altered composition is formed between composition inclined layers in a sandwiched manner, or another configuration such as a configuration in which there is inclination of composition in part of a layer. In the present embodiment described below, a case in which the composition within a composition inclined layer is constant and in which there is a stepwise inclination of composition from the proximal layer to the pseudo substrate layer is described. By providing a plurality of composition inclined layers in this manner, it is possible to increase crystallinity of the pseudo substrate layer and effectively improve performance of a semiconductor layer.

Note that the lattice constant a_{c} (aₚ) of the pseudo substrate layer is the largest among the plurality of composition inclined layers and that, conversely, the lattice constant a_{c} of the proximal layer is the smallest among the plurality of composition inclined layers.

The plurality of (N in total) composition inclined layers are preferably stacked such that a degree of mismatch Y of a lattice constant (a_{c} or aₚ) of a composition inclined layer relative to a lattice constant (a_{c}) of a layer adjacent thereto at the off substrate-side (hereinafter, also referred to as an “underlayer”), which in other words is the degree of mismatch Y_{cn+1·cn} of a lattice constant a_{cn+1} of an n+^{th} composition inclined layer relative to a lattice constant a_{cn} of an n^{th} composition inclined layer, is preferably 0.05% or more, and is preferably 0.3% or less, and more preferably 0.15% or less.

By stacking the plurality of composition inclined layers such that the degree of mismatch Y_{cn+1·cn} is not less than the lower limit set forth above, it is possible to form a pseudo substrate layer having a large degree of mismatch Xβ_{p·g} with the substrate even without adopting a particularly large number N.

On the other hand, by stacking the plurality of composition inclined layers such that the degree of mismatch Y_{cn+1·cn} is not more than any of the upper limits set forth above, it is possible to inhibit the formation of threading dislocations in the composition inclined layers.

Although no specific limitations are placed on the composition inclined layers, inclusive of the pseudo substrate layer, so long as the degree of mismatch Xα_{p·g}, etc. satisfy specific requirements, these layers are preferably InAsP layers or InAlAs layers in a case in which the off substrate is an InP substrate.

Note that the composition inclined layers may be n-type layers or may be p-type layers.

The composition inclined layers, inclusive of the pseudo substrate layer, are preferably layers that are doped with Si (silicon) or the like.

The carrier density of the composition inclined layers is 1.0×10¹⁶/cm³ or more, for example, and may be 1.0×10¹⁷/cm³ or more. Moreover, the carrier density is 1.0×10¹⁹/cm³ or less, for example, and may be 1.0×10¹⁸/cm³ or less.

The number (corresponding to N in FIG. 2) of composition inclined layers, inclusive of the pseudo substrate layer, is preferably a natural number of 3 or more, and more preferably a natural number of 5 or more. With a natural number of 3 or more, crystallinity of the pseudo substrate layer can be further increased, and performance of a semiconductor layer can be more effectively improved.

On the other hand, the upper limit for N is dependent on the relationship between the lattice constant of the off substrate and the lattice constant of the pseudo substrate layer, and also on the relationship between the lattice constant of the pseudo substrate layer and the lattice constant of a subsequently described semiconductor layer, but the upper limit is 15 or less, for example, and may be 9 or less.

The plurality of composition inclined layers may have misfit dislocations at an off substrate-side of each of the composition inclined layers. Although the plurality of composition inclined layers may have a misfit dislocation in every one of the composition inclined layers or may have a misfit dislocation in a portion of the composition inclined layers, they preferably have a misfit dislocation at the off substrate-side of the proximal layer.

Note that misfit dislocations in the composition inclined layers can be confirmed through observation of a cross-section of the composition inclined layers using a transmission electron microscope (TEM), for example.

The pseudo substrate layer is a composition inclined layer that is furthest from the off substrate among the plurality of composition inclined layers.

The pseudo substrate layer is a layer that can serve as a substrate for epitaxial growth of a semiconductor layer in production of an optical semiconductor element.

It is preferable that the pseudo substrate layer is a thickest layer among the composition inclined layers and has a thickness of 300 nm or more from a viewpoint of improving crystallinity, with the thickness preferably being 500 nm or more, more preferably 1 μm or more, and even more preferably 2 μm or more.

Note that the thickness of the pseudo substrate layer is 10 μm or less, for example, from a viewpoint of avoiding an excessively long growth time.

The thickness of each composition inclined layer other than the pseudo substrate layer is preferably set as a thickness that exceeds the critical film thickness relative to the lattice constant difference with the proximal layer and causes the formation of misfit dislocations while also enabling relaxation of internal stress.

Specifically, the thickness of each composition inclined layer is preferably 300 nm or more, and more preferably 600 nm or more. Moreover, the thickness of each composition inclined layer is preferably 1,500 nm or less, and more preferably 1,200 nm or less.

### <Buffer Layer>

The buffer layer is a layer that can be provided between the off substrate and the proximal layer.

The buffer layer is a normally a layer that is lattice matched with the off substrate and preferably has the same composition as the off substrate. For example, the buffer layer is preferably an InP layer in a case in which the off substrate is an InP substrate.

Note that the buffer layer may be an n-type layer or may be a p-type layer.

The buffer layer is preferably a layer that is doped with Si or the like.

The carrier density of the buffer layer is 1.0×10¹⁶/cm³ or more, for example, and may be 1.0×10¹⁷/cm³ or more. Moreover, the carrier density is 1.0×10¹⁹/cm³ or less, for example, and may be 1.0×10¹⁸/cm³ or less.

The thickness of the buffer layer is 300 nm or more, for example, and may be 600 nm or more. Moreover, the thickness of the buffer layer is 2,000 nm or less, for example, and may be 1,500 nm or less.

### (Method of Producing Epitaxial Growth Substrate)

The method of producing an epitaxial growth substrate according to the present disclosure (hereinafter, also referred to simply as the “production method”) includes a step (composition inclined layer stacking step) of stacking, on an off substrate having a lattice constant a_{g} and an off angle θ, a plurality of composition inclined layers such that a lattice constant difference with the off substrate increases gradually from an off substrate-side. Moreover, in the production method according to the present disclosure, a composition inclined layer furthest from the off substrate is taken to be a pseudo substrate layer, and the pseudo substrate layer is formed such that a degree of mismatch Xα_{p·g} that, using a surface lattice constant a_{g}′ calculated from the lattice constant a_{g} and the off angle θ by formula (1), shown below:

$${a}_{g}^{′} = {a}_{g} / cos θ \qquad ( 1 )$$

and a strain-affected lattice constant bₚ of the pseudo substrate layer calculated from X-ray diffraction measurement results, is calculated by formula (2), shown below:

$$X {α}_{p \cdot g} = ( {b}_{p} - {a}_{g}^{′} ) / {a}_{g}^{′} \qquad ( 2 )$$

is 0.5% or less.

With a production method such as set forth above, it is possible to obtain an epitaxial growth substrate that can impart excellent performance to an optical semiconductor element. Moreover, with a production method such as set forth above, it is possible to obtain the epitaxial growth substrate according to the present disclosure.

Note that the production method according to the present disclosure may optionally include a step (buffer layer formation step) of forming a buffer layer at a surface of the off substrate where the composition inclined layers are to be stacked before stacking of the composition inclined layers.

Preferred configurations of the epitaxial growth substrate, the off substrate, the composition inclined layers, and the optional buffer layer are as previously described. The following describes the composition inclined layer stacking step and the optional buffer layer formation step.

### <Composition Inclined Layer Stacking Step>

In the composition inclined layer stacking step, a plurality of composition inclined layers are stacked on a specific off substrate such that a lattice constant difference with the off substrate increases gradually from an off substrate-side. Moreover, a composition inclined layer furthest from the off substrate is taken to be a pseudo substrate layer, and the pseudo substrate layer is formed such that the degree of mismatch Xα_{p·g} is 0.5% or less, preferably 0.15% or less, and more preferably −0.15% or less, and is preferably formed such that the degree of mismatch Xα_{p·g} is −3.0% or more.

No specific limitations are placed on the method by which the composition inclined layers, inclusive of the pseudo substrate layer, are formed so long as the composition inclined layers can be epitaxially grown on the off substrate or on the optional buffer layer. For example, the method may be metal organic chemical vapor deposition (MOCVD), molecular beam epitaxy (MBE), sputtering, or the like.

In a case in which the composition inclined layers, inclusive of the pseudo substrate layer, are InAsP layers, for example, these layers can be formed by vapor phase growth on the off substrate or on the optional buffer layer by supplying trimethylindium (TMIn) as an In source, arsine (AsH₃) as an As source, and phosphine (PH₃) as a P source into a growth furnace such as to have a specific mixing ratio while also using a carrier gas. In a case in which a layer is to be made an n-type or a p-type, a gas of a dopant source should be further used as appropriate.

Composition inclined layers and a pseudo substrate layer satisfying requirements for the degree of mismatch Xα_{p·g}, etc. described above can be formed by changing the mixing ratio of feedstock gases to thereby control the composition ratios. Moreover, the thickness of each layer can be adjusted through the ratio of the amount of group III feedstock gas and the amount of group V feedstock gas, the growth temperature, and the growth time.

### <Buffer Layer Formation Step>

In the buffer layer formation step, a buffer layer is formed at a surface of the off substrate where the composition inclined layers are to be stacked before stacking of the composition inclined layers.

No specific limitations are placed on the method by which the buffer layer is formed so long as the buffer layer can be epitaxially grown on the off substrate, and any of the methods for forming the composition inclined layers described above can be adopted.

For example, in a case in which the buffer layer is an InP layer, the buffer layer can be formed by vapor phase growth on the off substrate by supplying trimethylindium (TMIn) as an In source and phosphine (PH₃) as a P source into a growth furnace such as to have a specific mixing ratio while also using a carrier gas. In a case in which the buffer layer is to be made an n-type or a p-type, a gas of a dopant source should be further used as appropriate.

The thickness of the buffer layer can be adjusted through the ratio of the amount of group III feedstock gas and the amount of group V feedstock gas, the growth temperature, and the growth time.

### (Optical Semiconductor Element)

The optical semiconductor element according to the present disclosure is an optical semiconductor element that is obtained using the epitaxial growth substrate according to the present disclosure set forth above. Moreover, the optical semiconductor element according to the present disclosure includes a semiconductor layer that is provided at a surface of the pseudo substrate layer of the epitaxial growth substrate according to the present disclosure set forth above and that is lattice matched with the pseudo substrate layer.

The optical semiconductor element according to the present disclosure may be an optical semiconductor element where the off substrate has been removed by etching or the like. In other words, the optical semiconductor element according to the present disclosure may be an optical semiconductor element that includes an off substrate, a plurality of composition inclined layers, and a light-absorbing layer in stated order, or may be an optical semiconductor element that includes a plurality of composition inclined layers and a light-absorbing layer.

Note that the optical semiconductor element according to the present disclosure may optionally include constituent elements other than the epitaxial growth substrate and the semiconductor layer (hereinafter, also referred to as “other constituent elements”). Examples of other constituent elements include a window layer, an anti-reflection layer, an electrode, and so forth.

The optical semiconductor element according to the present disclosure may be a semiconductor light-receiving element or may be a semiconductor light-emitting element.

In a case in which the optical semiconductor element according to the present disclosure is a semiconductor light-receiving element, the semiconductor layer is normally a light-absorbing layer.

On the other hand, in a case in which the optical semiconductor element according to the present disclosure is a semiconductor light-emitting element, the semiconductor layer is normally a light-emitting layer.

Note that although the following describes the optical semiconductor element according to the present disclosure using a semiconductor light-receiving element as an example, the optical semiconductor element according to the present disclosure is not limited to the following example.

### <Epitaxial Growth Substrate>

The epitaxial growth substrate according to the present disclosure set forth above is used as the epitaxial growth substrate.

### <Light-Absorbing Layer>

The light-absorbing layer is provided at the surface of the pseudo substrate layer such as to be lattice matched with the pseudo substrate layer. A lattice constant a of the light-absorbing layer is more preferably slightly smaller than that of the pseudo substrate layer. Moreover, a lattice constant b of the light-absorbing layer according to XRD measurement is more preferably lattice matched with the lattice constant bₚ of the pseudo substrate layer while also resulting in a lattice constant difference of close to zero.

The component composition of the light-absorbing layer can be selected as appropriate according to a central absorption wavelength. For example, the central absorption wavelength can be set as 2,000 nm to 3,000 nm. In this case, the light-absorbing layer can, in terms of component composition, be formed from a III-V compound semiconductor that is a combination of 2 to 6 elements, in total, selected from group III elements (Al, Ga, In) and group V elements (P, As, Sb), and can be InGaAs, for example. Alternatively, the light-absorbing layer may be InAs, InGaAlAs, or InGaAsP.

Note that the light-absorbing layer is preferably undoped.

Alternatively, the light-absorbing layer may be an n-type layer or may be a p-type layer.

The thickness of the light-absorbing layer is not specifically limited but is 500 nm or more, for example, and may be 1,000 nm or more. Moreover, the thickness of the light-absorbing layer is 5,000 nm or less, for example, and may be 3,000 nm or less.

The light-absorbing layer can be formed at the surface of the pseudo substrate layer by a conventional method that is commonly known without any specific limitations.

### <Window Layer>

An optional window layer can be provided at a surface of the light-absorbing layer (surface at the opposite side to the pseudo substrate layer).

Although the composition of the window layer can be selected as appropriate, it is preferable that the window layer is an InAsP layer in a case in which the pseudo substrate layer is an InAsP layer, and it is preferable that a lattice constant a of the window layer is lattice matched with the pseudo substrate layer, and more preferable that the window layer has the same composition as the pseudo substrate layer.

Note that the window layer may be an n-type layer or may be a p-type layer.

The window layer is preferably a layer that is doped with Si or the like.

The carrier density of the window layer is 1.0×10¹⁶/cm³ or more, for example, and may be 1.0×10¹⁷/cm³ or more. Moreover, the carrier density of the window layer is 1.0×10¹⁹/cm³ or less, for example, and may be 1.0×10¹⁸/cm³ or less.

The thickness of the window layer is not specifically limited but is 300 nm or more, for example, and may be 600 nm or more. Moreover, the thickness of the window layer is 2,000 nm or less, for example, and may be 1,500 nm or less.

The window layer can be formed at a surface of the light-absorbing layer (surface at the opposite side to the pseudo substrate layer) by a conventional method that is commonly known without any specific limitations.

After formation of the window layer, Zn may optionally be caused to diffuse from the window layer toward the light-absorbing layer by MOCVD or the like. Diethylzinc or the like, for example, can be used as a Zn source.

### <Anti-Reflection Layer>

An optional anti-reflection layer can be provided at a surface of the window layer (surface at the opposite side to the light-absorbing layer).

The anti-reflection layer can be selected as appropriate and may be a SiN film, or the like, for example.

The thickness of the anti-reflection layer is not specifically limited but is 50 nm or more, for example, and may be 100 nm or more. Moreover, the thickness of the anti-reflection layer is 600 nm or less, for example, and may be 300 nm or less.

The anti-reflection layer can be formed at a surface of the window layer (surface at the opposite side to the light-absorbing layer) by a conventional method that is commonly known such as CVD or application.

Note that the anti-reflection layer is normally patterned by photolithography using a resist, for example, at the surface of the window layer.

### <Electrode>

An optional electrode may be provided in electrical connection with the epitaxial growth substrate. For example, an electrode can be provided at a surface of the window layer, at a surface of the off substrate of the epitaxial growth substrate, etc. Note that the electrode may be a p-type electrode or may be an n-type electrode.

The electrode can be formed by a conventional method that is commonly known such as sputtering, electron beam vapor deposition, or resistive heating without any specific limitations.

### <Example of Optical Semiconductor Element>

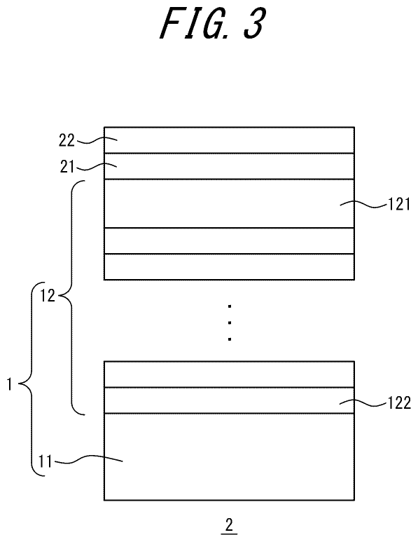

The following describes a semiconductor light-receiving element that is one embodiment of the optical semiconductor element according to the present disclosure with reference to FIG. 3, but the optical semiconductor element according to the present disclosure is not limited to this semiconductor light-receiving element. Note that in FIG. 3, aspect ratios of a substrate and each layer are illustrated in an exaggerated manner without consideration of their actual thickness in order to facilitate description.

FIG. 3 is a schematic view illustrating an example of a semiconductor light-receiving element that is one embodiment of the optical semiconductor element according to the present disclosure.

A semiconductor light-receiving element 2 illustrated in FIG. 3 includes an epitaxial growth substrate 1, a light-absorbing layer 21, and a window layer 22 in stated order. The epitaxial growth substrate 1 includes an off substrate 11 and a plurality of composition inclined layers 12, wherein a composition inclined layer 12 furthest from the off substrate 11 is a pseudo substrate layer 121, and a composition inclined layer 12 closest to the off substrate 11 is a proximal layer 122. The light-absorbing layer 21 is provided at a surface of the pseudo substrate layer 121.

In other words, the semiconductor light-receiving element 2 includes an off substrate 11, a plurality of composition inclined layers 12, a light-absorbing layer 21, and a window layer 22 in stated order and has the light-absorbing layer 21 provided at a surface of the pseudo substrate layer 121.

### Examples

The following provides an even more detailed description of the present disclosure using examples. However, the present disclosure is not limited to the following examples.

Note that a lattice constant a and a lattice constant bₚ were measured or calculated by the methods that were previously described.

### Example 1

### Production of Epitaxial Growth Substrate

First, trimethylindium (TMIn) as an In source, trimethylgallium (TMG) as a Ga source, arsine (AsH₃) as an As source, and phosphine (PH₃) as a P source were prepared as feedstock gases.

An n-type InP buffer layer was deposited by MOCVD on a (100) face of an n-type InP substrate (3 inches; substrate thickness: 625 μm; lattice constant: 0.5869 nm; off angle in [110] direction from (100) plane: 6°) serving as an off substrate.

Next, trimethylindium, arsine, and phosphine were used as feedstock gases to perform vapor phase growth by MOCVD on the n-type InP buffer layer while changing the amount of P (P gas phase ratio) relative to the total of As and P contained in the feedstock gases to thereby deposit n-type InAsₓP₁₋ₓ composition inclined layers 1 to 6 and obtain an epitaxial growth substrate. The composition inclined layer 6 furthest from the n-type InP substrate was taken to be a pseudo substrate layer.

Note that various formation conditions and values of lattice constants for the epitaxial growth substrate in which the n-type InP substrate, the n-type InP buffer layer, and the n-type InAsₓP₁₋ₓ composition inclined layers 1 to 6 (up to the pseudo substrate layer) were formed are presented in Table 2.

### <Production of Semiconductor Light-Receiving Element>

Separately to the epitaxial growth substrate described above, an undoped InGaAs light-absorbing layer (semiconductor layer) and an n-type InAsP window layer were sequentially deposited on a surface of a pseudo substrate layer of an epitaxial growth substrate that was obtained in the same way as described above. Note that various formation conditions and values of lattice constants for the InGaAs light-absorbing layer and the InAsP window layer are presented in Table 2.

Next, a mask formed of Si₃N₄ was formed on the InAsP window layer, and a mask opening was formed by etching. MOCVD was subsequently adopted to cause a Zn source to flow and Zn to diffuse from the n-type InAsP window layer at the mask opening into part of the n-type InGaAs light-absorbing layer (up to a depth of 0.3 μm at the light-absorbing layer-side from an interface between the window layer and the light-absorbing layer) such as to give an average Zn concentration of 5.0×10¹⁸/cm³ and cause conversion to a p-type. Note that DEZn (diethylzinc) was used as the Zn source.

Next, a 0.2 μm Si₃N₄ film (anti-reflection layer) was deposited over the entire surface by CVD, the Si₃N₄ film was patterned by photolithography using a resist, and an exposed section exposing part of a periphery of the region that had been converted to a p-type was formed.

In addition, electron beam vapor deposition was adopted to form a p-type electrode in connection with the window layer that had been converted to a p-type at the exposed section and to form a rear surface electrode at a rear surface of the n-type InP substrate, thereby resulting in a semiconductor light-receiving element equipped with electrodes.

### Example 2

An epitaxial growth substrate and an optical semiconductor element were obtained in the same way as in Example 1 with the exception that an n-type InP substrate having an off angle of 100 was used as the off substrate and that various formation conditions and properties of the layers were changed as indicated in Table 3.

### Example 3

An epitaxial growth substrate and an optical semiconductor element were obtained in the same way as in Example 1 with the exception that an n-type InP substrate having an off angle of 15° was used as the off substrate and that various formation conditions and properties of the layers were changed as indicated in Table 3.

### Comparative Example 1

An epitaxial growth substrate and an optical semiconductor element were obtained in the same way as in Example 1 with the exception that an n-type InP substrate having an off angle of 2° was used as the off substrate and that various formation conditions and properties of the layers were changed as indicated in Table 3.

### Comparative Example 2

An epitaxial growth substrate and an optical semiconductor element were obtained in the same way as in Example 1 with the exception that an n-type InP substrate having an off angle of 0° was used instead of an off substrate and that various formation conditions and properties of the layers were changed as indicated in Table 3.

### (Full Width at Half Maximum of Rocking Curve of Pseudo Substrate Layer)

The epitaxial growth substrates obtained in the examples and comparative examples were each used to calculate the full width at half maximum (FWHM) of a rocking curve of the pseudo substrate layer according to X-ray crystallography (XRC) by the following method.

Specifically, an X-ray diffractometer D8 produced by Bruker was used to perform reciprocal space mapping (RSM) of (004) planes, and then the full width at half maximum of a rocking curve was determined from the resulting ω direction profile using analysis software LEPTOS. The results are presented in Table 3.

Note that a smaller rocking curve full width at half maximum indicates that a semiconductor layer having better crystallinity is obtained.

### (Measurement of Dark Current)

The semiconductor light-receiving elements obtained in Example 1 and Comparative Example 1 were each used to measure the dark current of the semiconductor light-receiving element. Specifically, a “model-2635B” source measure unit produced by Keithley Instruments was used to perform measurement by a two-terminal method with application of bias voltages of Vr=−0.01 V and −0.1 V. The results are presented in Table 4.

Note that when a semiconductor light-receiving element has a smaller dark current, this indicates that the semiconductor light-receiving element has better performance.

In Tables 2 and 3:

“Lattice constant a” means lattice constant a_{g} of off substrate and lattice constant of each layer (lattice constant a_{c} of composition inclined layer, lattice constant aₚ of pseudo substrate layer, etc.) according to Vegard's law;

“Surface lattice constant a_{g}′” means value calculated by dividing lattice constant a_{g} by cosθ (θ is the off angle) (i.e., “a_{g}/cosθ”);

“Lattice constant bₚ” indicates strain-affected lattice constant bₚ of pseudo substrate layer calculated from XRD measurement results; and

“Y” means degree of mismatch of each layer relative to layer (underlayer) adjacent thereto at off substrate-side.

“Xα_{p·g}” is a degree of mismatch of a pseudo substrate layer relative to an off substrate and means (bₚ−a_{g}′)/a_{g}′, which takes into account an off angle.

“Xβ_{p·g}” is a degree of mismatch of a pseudo substrate layer relative to an off substrate and means (bₚ−a_{g})/a_{g}, which does not take into account an off angle.

TABLE 2

| | | | | | | Degree of | | |
|---|---|---|---|---|---|---|---|---|
| | | | | | | mismatch | | |
| | | | Carrier | | Vegard's | of lattice | | XRD |
| | | | density | | law | constant a | Surface | measurement |
| | | | before Zn | | lattice | relative to | lattice | lattice |
| | | | diffusion | Thickness | constant | underlayer | constant | constant |
| Example 1 | Composition | Dopant | [/cm³] | [μm] | a [nm] | Y [%] | a_{g}′ [nm] | bₚ [nm] |
| n-Type InAsP window layer | InAs_{0.23}P_{0.77} | Si | 5.00 × 10¹⁶ | 1.5 | 0.5912 | 0.05 | — | — |
| InGaAs light-absorbing layer | In_{0.632}Ga_{0.368}As | Undoped | — | 3.0 | 0.5909 | −0.05 | — | — |
| n-Type InAsP composition inclined layer | InAs_{0.23}P_{0.77} | Si | 7.50 × 10¹⁷ | 2.7 | 0.5912 | 0.12 | — | 0.5904 |
| (pseudo substrate layer) | | | | | | | | |
| n-Type InAsP composition inclined layer | InAs_{0.19}P_{0.81} | Si | 7.50 × 10¹⁷ | 0.73 | 0.5905 | 0.12 | — | — |
| n-Type InAsP composition inclined layer | InAs_{0.15}P_{0.85} | Si | 7.50 × 10¹⁷ | 0.73 | 0.5898 | 0.12 | — | — |
| n-Type InAsP composition inclined layer | InAs_{0.11}P_{0.89} | Si | 7.50 × 10¹⁷ | 0.73 | 0.5891 | 0.12 | — | — |
| n-Type InAsP composition inclined layer | InAs_{0.07}P_{0.93} | Si | 7.50 × 10¹⁷ | 0.73 | 0.5883 | 0.12 | — | — |
| n-Type InAsP composition inclined layer | InAs_{0.03}P_{0.97} | Si | 7.50 × 10¹⁷ | 0.73 | 0.5876 | 0.12 | — | — |
| n-Type InP buffer layer | InP | Si | 7.00 × 10¹⁷ | 0.4 | 0.5869 | — | — | — |
| n-Type InP substrate having off angle | InP | S | 3.00 × 10¹⁸ | 625 | 0.5869 | — | 0.5901 | — |
| θ of 6° (off substrate) | | | | | | | | |

TABLE 3

| | | | | Pseudo substrate layer | | | | |
|---|---|---|---|---|---|---|---|---|
| | | | | | | Degree of mismatch relative to off | | |
| | Off substrate | | | | XRD | substrate [%] | | |
| | | | Surface | Vegard's | measurement | Taking into | Not taking into | Full width at |
| | Lattice | Off | lattice | law lattice | lattice | account off | account off | half |
| | constant | angle | constant | constant | constant | angle θ | angle θ | maximum of |
| | a_{g} | θ | a_{g}′ | aₚ | bₚ | Xα_{p·g} = | Xβ_{p·g} = | rocking curve |
| | [nm] | [°] | [nm] | [nm] | [nm] | (bₚ − a_{g}′)/a_{g}′ | (bₚ − a_{g})/a_{g} | [arcsec] |
| Comparative | 0.5869 | 0 | 0.5869 | 0.5912 | 0.5907 | 0.65 | 0.65 | 593 |
| Example 2 | | | | | | | | |
| Comparative | 0.5869 | 2 | 0.5873 | 0.5912 | 0.5908 | 0.60 | 0.66 | 432 |
| Example 1 | | | | | | | | |
| Example 1 | 0.5869 | 6 | 0.5901 | 0.5912 | 0.5904 | 0.05 | 0.60 | 254 |
| Example 2 | 0.5869 | 10 | 0.5960 | 0.5912 | 0.5904 | −0.94 | 0.60 | 219 |
| Example 3 | 0.5869 | 15 | 0.6076 | 0.5912 | 0.5904 | −2.83 | 0.60 | 146 |

TABLE 4

Dark current [A]

| | −0.01 V | −0.1 V |
|---|---|---|
| Example 1 | 1.05 | 8.16 |
| Comparative | 1.33 | 8.93 |
| Example 1 | | |

As can clearly be seen from Table 3, the epitaxial growth substrates of Examples 1 to 3 have improved pseudo substrate layer crystallinity compared to the epitaxial growth substrates of Comparative Examples 1 and 2 since the full width at half maximum of a rocking curve for the pseudo substrate layer is smaller. Consequently, the epitaxial growth substrates of Examples 1 to 3 can be said to be capable of imparting excellent performance to an optical semiconductor element. This can also be understood from the result that the dark current of the semiconductor light-receiving element of Example 1, which has a small rocking curve full width at half maximum, is smaller than that of the semiconductor light-receiving element of Comparative Example 1, as indicated in Table 4.

### INDUSTRIAL APPLICABILITY

According to the present disclosure, it is possible to provide an epitaxial growth substrate that can impart excellent performance to an optical semiconductor element.

Moreover, according to the present disclosure, it is possible to provide a method of producing an epitaxial growth substrate that can impart excellent performance to an optical semiconductor element.

Furthermore, according to the present disclosure, it is possible to provide an optical semiconductor element having excellent performance.

1. An epitaxial growth substrate comprising:
an off substrate having a lattice constant a_{g} and an off angle θ; and
a plurality of composition inclined layers stacked such that a lattice constant difference with the off substrate increases gradually from an off substrate-side, wherein
a composition inclined layer furthest from the off substrate is taken to be a pseudo substrate layer, and
a degree of mismatch Xα_{p·g} that, using a surface lattice constant a_{g}′ calculated from the lattice constant a_{g} and the off angle θ by formula (1), shown below:
$${a}_{g}^{′} = {a}_{g} / cos θ \qquad ( 1 )$$
and a strain-affected lattice constant bₚ of the pseudo substrate layer calculated from X-ray diffraction measurement results, is calculated by formula (2), shown below:
$$X {α}_{p \cdot g} = ( {b}_{p} - {a}_{g}^{′} ) / {a}_{g}^{′} \qquad ( 2 )$$
is 0.5% or less.

2. The epitaxial growth substrate according to claim 1, wherein
a degree of mismatch Xβ_{p·g} calculated by formula (3), shown below:
$$X {β}_{p \cdot g} = ( {b}_{p} - {a}_{g} ) / {a}_{g} \qquad ( 3 )$$
is more than 0.5%, and
the degree of mismatch Xα_{p·g} is not less than −3.0% and not more than 0.5%.

3. The epitaxial growth substrate according to claim 1, wherein the off angle θ is not less than 4° and not more than 44°.

4. The epitaxial growth substrate according to claim 1, wherein the plurality of composition inclined layers are stacked such that a degree of mismatch Y of a lattice constant of a composition inclined layer relative to a lattice constant of a layer adjacent thereto at an off substrate-side is not less than 0.05% and not more than 0.3%.

5. The epitaxial growth substrate according to claim 1, wherein the off substrate is an InP substrate, and the composition inclined layers are InAsP layers or InAlAs layers.

6. The epitaxial growth substrate according to claim 1, wherein the pseudo substrate layer is a thickest layer among the composition inclined layers, and the pseudo substrate layer has a thickness of 300 nm or more.

7. A method of producing an epitaxial growth substrate comprising a step of stacking, on an off substrate having a lattice constant a_{g} and an off angle θ, a plurality of composition inclined layers such that a lattice constant difference with the off substrate increases gradually from an off substrate-side, wherein
a composition inclined layer furthest from the off substrate is taken to be a pseudo substrate layer, and
the pseudo substrate layer is formed such that a degree of mismatch Xα_{p·g} that, using a surface lattice constant a_{g}′ calculated from the lattice constant a_{g} and the off angle θ by formula (1), shown below:
$${a}_{g}^{′} = {a}_{g} / cos θ \qquad ( 1 )$$
and a strain-affected lattice constant bₚ of the pseudo substrate layer calculated from X-ray diffraction measurement results, is calculated by formula (2), shown below:
$$X {α}_{p \cdot g} = ( {b}_{p} - {a}_{g}^{′} ) / {a}_{g}^{′} \qquad ( 2 )$$
is 0.5% or less.

8. An optical semiconductor element obtained using the epitaxial growth substrate according to claim 1, comprising a semiconductor layer that is provided at a surface of the pseudo substrate layer of the epitaxial growth substrate and that is lattice matched with the pseudo substrate layer.
